(19) United States
(12) Patent Application Publication
(10) Pub. No.: US 2011/0184678 A1
(43) Pub. Date: Jul. 28, 2011

(54) AUTOMATED SYSTEMS AND METHODS FOR CHARACTERIZING LIGHT-EMITTING DEVICES

(75) Inventors: RAND W. LEE, Seattle, WA (US); MATTHEW G. PIATT, Kirkland, WA (US); DAVID P. BAJORINS, Bothell, WA (US); KRIS YOUNG, Cottage Grove, OR (US); CHACE H. FADLOVICH, Bothell, WA (US)

(73) Assignee: ORB OPTRONIX INC

(21) Appl. No.: 12/874,274

(22) Filed: Sep. 2, 2010

Related U.S. Application Data
(60) Provisional application No. 61/336,675, filed on Jan. 25, 2010.

(51) Int. Cl. G06F 19/00; G01R 19/00; G01R 23/00

(52) U.S. Cl. 702/64; 702/75; 702/85; 702/66

(57) ABSTRACT

Automated systems and methods for characterizing light-emitting devices as a function of the electrical and temperature properties of the device are disclosed. The system includes a thermal stack assembly operatively connected to a temperature control system and that operably supports and controls the temperature of the light-emitting device. A power supply provides varying amounts of electrical power to the light-emitting device. A control computer controls the power supply and the temperature control system based on a user-defined electrical and temperature profiles. A light processor optically analyzes light from the light-emitting device as its electrical and temperature properties are varied. The control computer receives and processes electrical signals from the light processor and outputs one or more optical characterizations as a function of electrical and temperature properties of the light-emitting device.

### CLAIM OF PRIORITY

This application claims the benefit of priority under 35 U.S.C. §119(e) of U.S. Provisional Application Ser. No. 61/336,675, filed on Jan. 25, 2010, and entitled “Automated systems and methods for characterizing light-emitting devices,” and which is incorporated by reference herein.

### FIELD

The disclosure relates to light-emitting devices, and in particular relates to automated systems and methods for characterizing light-emitting devices.

### BACKGROUND ART

Light-emitting devices can be characterized by their optical output under a variety of operating conditions based on parameters such as applied electrical power (e.g., current or voltage), and device temperature. Such characterization is important because light-emitting devices are used in a wide range of systems over a wide range of operating conditions, and the performance of such systems is often based on the performance of the light-emitting device.

By way of example, color displays such as liquid-crystal displays (LCDs) may employ red (R), green (G) and blue (B) light-emitting diodes (LEDs) to define an RGB color gamut used to display color images. If the operating conditions (e.g., temperature) change, this will affect the optical output of one or more of the R, G and B LEDs. These changes will alter the possible color gamut and optical power level that can be realized by the system and fundamentally affect the fidelity of the color display. This general concept applies to any ambient or task lighting (luminaire) that requires accurate color reproducibility.

Presently, measuring the optical characteristics of a light-emitting device is done manually using custom-built fixtures and test equipment. This manual approach is time intensive and labor intensive and is prone to operator error. The tediousness of these measurements is due to the fact that an operator must manually control and continuously monitor the fixtures and test equipment, adjust the various measurement parameters and conditions, record the measured optical values, and then process and display the optical, electrical, and temperature (thermal) values.

### SUMMARY

The present disclosure is directed to systems and methods for characterizing the optical output of a light-emitting device as a function of the electrical power applied to and the temperature of the light-emitting device.

An aspect of the disclosure is an optical characterization system having a thermal stack assembly that is operatively connected to a temperature control system. The thermal stack assembly operably supports and controls the temperature of the light-emitting device under test. A power supply provides electrical power to the light-emitting device under test and controls the amount of electrical power provided. The electrical power can be provided in a variety of forms, such as DC, AC, pulse-width modulated current, voltage control, etc.

The system can drive a single current or voltage channel, or multiple current or voltage channels under any of the previously mentioned modes. A control computer manages the power supply and the temperature control system according to user-defined electrical and temperature profiles to vary, in a controlled manner, the amount of electrical current or voltage delivered to the light-emitting device, and to control the device temperature. The temperature control system is thus configured to remove or add heat to the light-emitting device as needed to maintain it at a temperature set point, as well as to change the temperature in accordance with different set points.

A light processor optically analyzes (processes) the light from the light-emitting device as operating parameters of the light-emitting device are varied. The light processor generates electrical signals representative of the processed light. In some embodiments, a light-collecting device, such as an optical system or a light-integrating device (e.g., a light-integrating sphere) is used to collect the light prior to the light processor receiving the light. The control computer receives and processes the electrical signals from the light processor and outputs an optical characterization as a function of electrical and/or thermal properties of the light-emitting device.

It is to be understood that both the foregoing general description and the following detailed description set forth example embodiments of the disclosure, and are intended to provide an overview or framework for understanding the nature and character of the disclosure as it is claimed. The accompanying drawings are included to provide a further understanding of the disclosure, and are incorporated into and constitute a part of this specification. The drawings illustrate various embodiments of the disclosure and together with the description serve to explain the principles and operations of the disclosure.

### BRIEF DESCRIPTION OF THE DRAWINGS

FIG. 1A is a schematic diagram of an example of the optical characterization system of the disclosure that includes a light processor and a light-collecting device in the form of a light-integrating sphere;

FIG. 1B is a schematic diagram similar to FIG. 1A, wherein the light-collecting device is in the form of an optical system;

FIG. 1C is a schematic diagram similar to FIG. 1B, wherein the light processor and the light-emitting device are in direct optical communication;

FIG. 2 is a more detailed schematic diagram of an example embodiment of the optical characterization system;

FIG. 3 is a flow diagram that sets forth an example electrical control and feedback process for the optical characterization system;

FIG. 4 is a flow diagram that sets forth an example temperature control and feedback process for the optical characterization system;

FIG. 5 is a flow diagram that sets forth an example light processor control process for the optical characterization system;

FIG. 6 is a flow diagram that sets forth an example measurement control process for the optical characterization system;

FIG. 7 is a flow diagram that sets forth an example calibration control process for the optical characterization system;

FIG. 8 is a flow diagram that sets forth an example lamp transfer process for the optical characterization system;

FIG. 9 is a plot of the radiant flux (Watts) versus wavelength (nm) for an amber LED as the light-emitting device under test, wherein the optical characterization system varied the temperature and electrical current of the light-emitting device to obtain the different spectra shown in the plot, wherein the curves were generated based on the temperature profile and electrical profile of FIG. 10;

FIG. 10 plots both temperature (° C.) and current (A) versus step number, and shows the temperature profile and electrical profile implemented by the control computer in the optical characterization system obtaining the curves shown in FIG. 9, FIG. 11 and FIG. 12;

FIG. 11 is a plot of the luminous efficacy (lm/W) vs. electrical current (A) for an amber LED as the light-emitting device under test, wherein the curves were generated based on the temperature profile and electrical profile of FIG. 10; and

FIG. 12 is a plot of the luminous flux (lm) vs. electrical current (A) for an amber LED as the light-emitting device under test, wherein the curves were generated based on the temperature profile and electrical profile of FIG. 10.

The various elements depicted in the drawing are merely representational and are not necessarily drawn to scale. Certain sections thereof may be exaggerated, while others may be minimized. The drawing is intended to illustrate an example embodiment of the disclosure that can be understood and appropriately carried out by those of ordinary skill in the art.

### DETAILED DESCRIPTION

In the discussion below, the term “light processor” is used to describe a device that receives light and in response thereto generates an electrical output (electrical signal) representative of an optical property of the detected light. Example light processors include the various types of spectrometers (including spectrophotometers, scanning monochromator, etc.) and various types of colorimeters.

Also, the concept of providing “electrical power” as used herein includes providing an electrical current or an electrical voltage, since electrical power is a function of both current and the voltage.

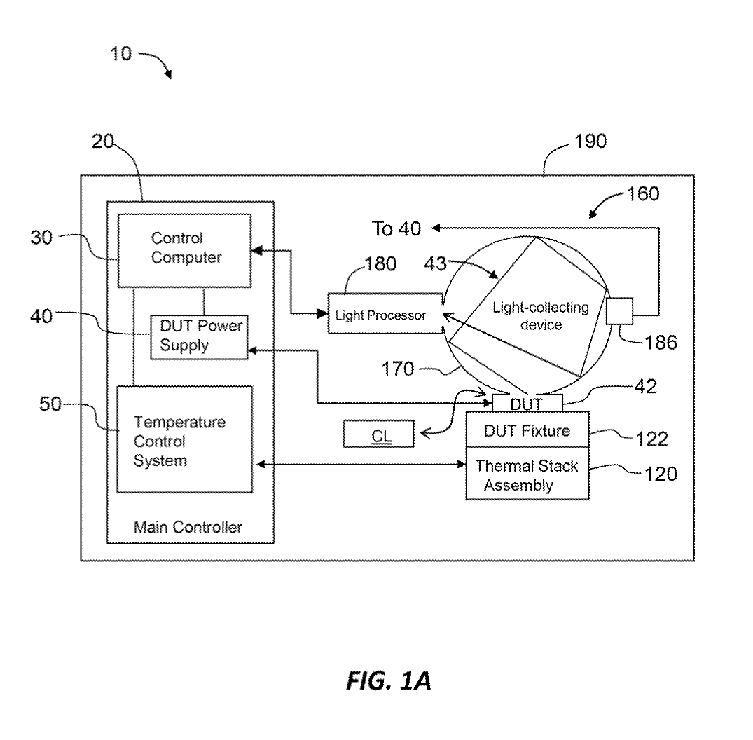

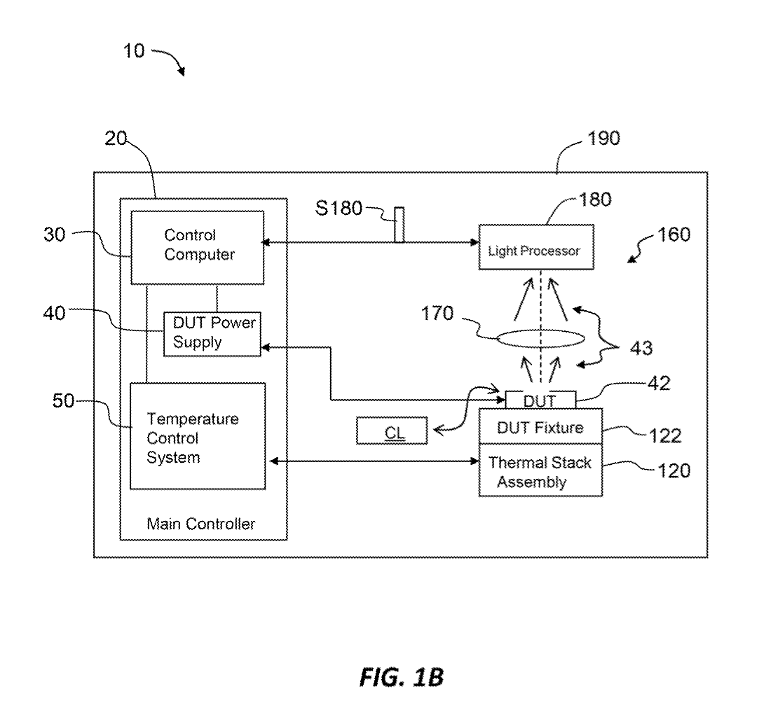

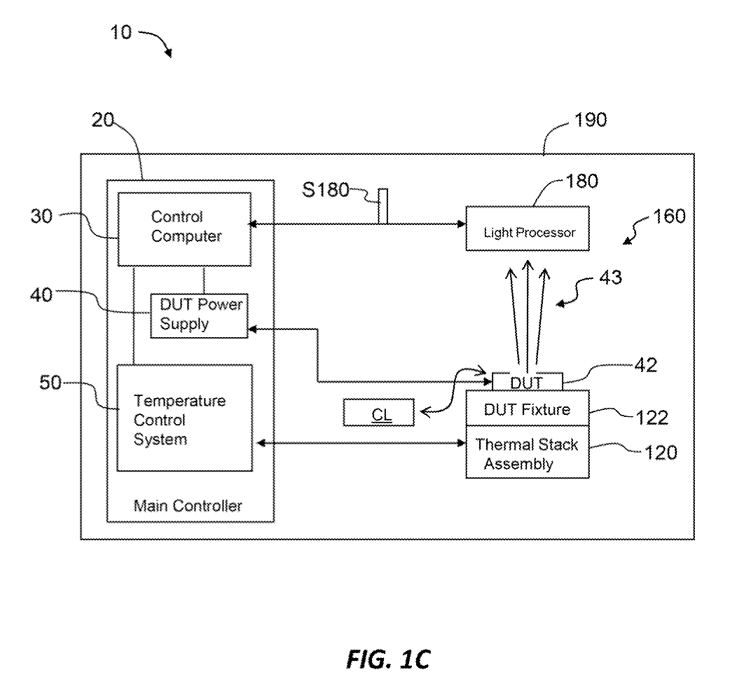

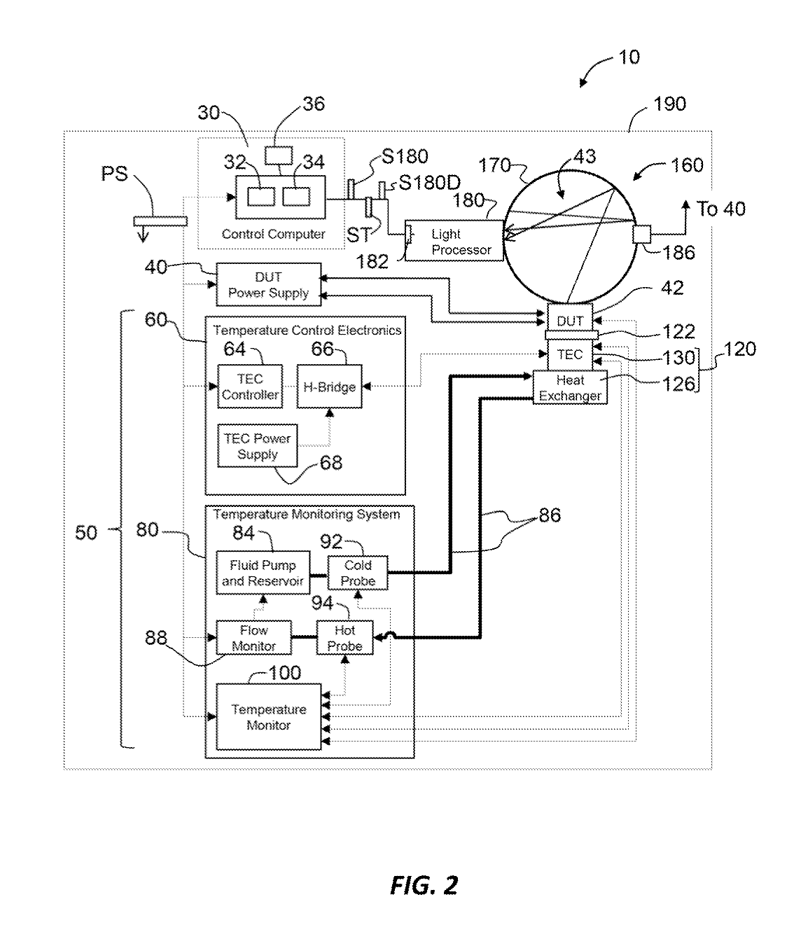

FIGS. 1A-1C show several example embodiments of the optical characterization system (“system”) 10 of the disclosure, and FIG. 2 is a more detailed schematic diagram of an example system.

With reference first to FIG. 1A, system 10 has a main controller 20 that includes a control computer 30 configured to control the overall operation of system 10 according to a set of instructions, such as in the form of one or more user-defined profiles as described below. Main controller 20 also includes a device-under-test (DUT) power supply 40 electrically connected to control computer 30 and also electrically connected (e.g., via two or more pairs of electrical leads) to a light-emitting device under test (hereinafter, “DUT”) 42 to provide electrical power thereto. FIG. 1A also shows a calibration lamp CL that can be swapped in and out with DUT 42, a DUT fixture 122, and a thermal stack assembly 120 to perform system calibration, as described below. DUT power supply 40 can also reside outside of main controller 20.

Main controller 20 also includes a temperature control system 50 electrically connected to control computer 30 and operatively (e.g., electrically and fluidly) connected to a thermal stack assembly 120 that operably supports DUT 42 with the aforementioned DUT fixture 122. Thermal stack assembly 120 is configured to be in thermal communication with DUT 42 and is thus used to vary the temperature of the DUT under the control of temperature control system 50, as described in greater detail below.

System 10 also includes an optical measurement assembly 160 that in the example of FIG. 1A includes a light-collecting device 170 such as a light-integrating sphere or an optical system, and a light processor 180 optically coupled thereto. Light processor 180 includes a photosensor 182 (FIG. 2) and is electrically connected to control computer 30. In an embodiment of system 10, optical measurement assembly 160 also includes an auxiliary lamp 186 optically coupled to light-collecting device 170 and electrically connected to DUT power supply 40. Light-collecting device 170 is configured to collect light 43 from DUT 42 (see, e.g., FIG. 1B, FIG. 2) and direct it to or otherwise make it available to light processor 180.

DUT fixture 122 is configured to operably support DUT 42 so that the DUT is optically coupled to light-collecting device 170 while also being in thermal communication with thermal stack assembly 120 and in electrical contact with DUT power supply 40.

System 10 also optionally includes a housing 190 that encloses some or all of the above-described system components.

FIG. 1B is a schematic diagram of system 10 similar to FIG. 1A, wherein light-collecting device 170 is in the form of an optical system that collects light 43 from DUT 42 and directs it to light processor 180.

FIG. 1C is a schematic diagram of system 10 similar to FIG. 1B, wherein the light processor 180 and DUT 42 are in direct optical communication, i.e., there is no intervening light-collecting device 170 used to collect light. Note that a system 10 that includes a fold mirror in between light processor 180 and DUT 42 is encompassed by system 10 of FIG. 1C since a fold mirror does not collect light per se, but merely reflects light.

### Control Computer

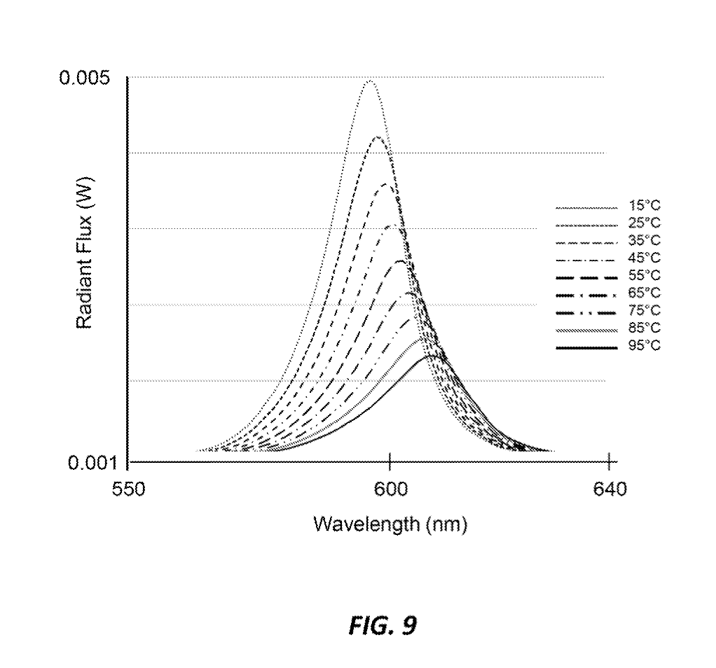

With reference now to FIG. 2, control computer 30 includes a processing unit (“processor”) 32 and a memory unit (“memory”) 34 electrically connected to the processor. Control computer 30 also includes or is electrically connected to a display unit 36 for displaying optical characterization information as outputted by processor 32 or as stored in memory 34. Example displayed optical characterization information can be provided in the form of plots such as those shown in FIGS. 9-12, i.e., charts, graphs, and like graphical and alpha-numeric representations.

Processor 32 is adapted to receive and process raw signals 5180 from light processor 180 or from memory 34, as described in greater detail below. In an example embodiment, processor 32 is or includes any processor or device capable of executing a series of software instructions and includes, without limitation, a general- or special-purpose microprocessor, finite state machine, controller, computer, central-processing unit (CPU), field-programmable gate array (FPGA), digital signal processor, and the like.

Memory 34 includes any processor-readable or computer-readable medium, including but not limited to RAM, ROM, EPROM, PROM, EEPROM, disk, floppy disk, hard disk, CD-ROM, DVD, or the like, on which may be stored a series of instructions (“software”) executable by processor 32. Memory 34 can also be used to store raw optical data embodied in signals 5180 from light processor 180, as well as processed optical data from processed signals S180.

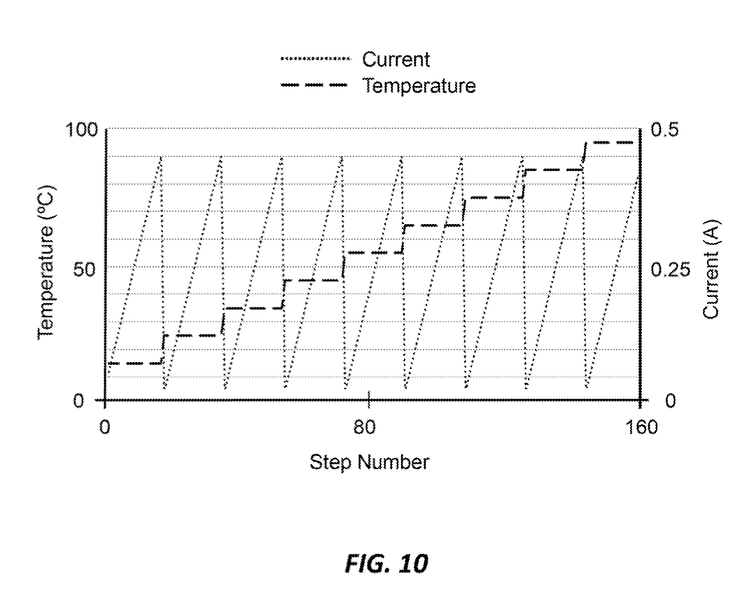

In one example, a user or operator defines electrical and temperature profiles for software maintained in control computer 30 so that the control computer can automatically vary, in a controlled manner, the electrical input to and the temperature of DUT 42 via the controlled operation of temperature control system 50 and DUT power supply 40. In example embodiments, the electrical and temperature profiles are executed by the electrical and temperature control and feedback processes, which are described in detail below, and an example of which is shown in FIG. 10.

In example embodiments, an operator also uses the software to view real-time test results (e.g., on display unit 36), execute calibration and lamp transfers, and manage lamp and calibration files as required. In short, the software in control computer 30 causes the control computer to run automated sequences of DUT electrical power and/or DUT temperature based on one or more user-defined electrical and temperature profiles. Example software suitable for use in control computer 30 is the SPECTRALSUITE software, by Orb Optronix, Inc., Kirkland, Wash.

In an example embodiment, control computer 30 is configured to trigger light processor 180 with trigger signal ST that is synchronous with a power supply signal PS that activates DUT power supply 40 (see FIG. 2). In another example, power supply signal PS is a pulse-width modulation (PWM) signal having a period, and light processor 180 has an integration time that is an integer multiple of the PWM period.

### Temperature Control System and Thermal Stack Assembly

With reference to FIG. 2, an example temperature control system 50 includes temperature control electronics 60 and a temperature monitoring system 80. An example embodiment of temperature control electronics 60 includes a thermoelectric cooler (TEC) controller 64, a TEC power supply 68 electrically connected to the TEC controller, and an H-bridge 66 electrically connected to the TEC controller.

An example temperature monitoring system 80 includes a fluid pump and reservoir 84 that is fluidly connected to or is otherwise in fluid communication with thermal stack assembly 120 via tubing 86 or via an air flow path. Fluid pump and reservoir 84 circulates a cooling fluid, such as a cooling liquid in the form of water or propylene glycol, or a cooling gas (e.g., air), to the thermal stack assembly via tubing 86. A flow monitor 88 is connected in-line with tubing 86 to measure the flow rate of the cooling fluid. Temperature probes 92 and 94 are configured in tubing 86 to measure the cooling fluid temperature, and are electrically connected (e.g., via thermocouple wiring) to a temperature monitor 100.

An example thermal stack assembly 120 includes a heat exchanger 126 in thermal communication with a TEC unit 130, which is electrically connected to TEC controller 64 in temperature control electronics 60, and is in thermal communication with DUT 42 via DUT fixture 122. Heat exchanger 126 is in fluid communication with fluid pump and reservoir 84 via tubing 86, and serves to dissipate heat from TEC unit 130. In temperature control electronics 60, TEC controller 64 is connected to H-bridge 66 to regulate the power output of TEC power supply 68, which sets the temperature of TEC unit 130. In an example embodiment, fluid pump and reservoir 84 can include a fan that blows air onto heat exchanger 126 either directly or through tubing 86. It is noted that such air cooling constitutes a form of fluid communication between temperature monitoring system 80 and thermal stack assembly 120.

Temperature monitor 100 of temperature monitoring system 80 is electrically connected (e.g., via thermocouple wiring) to various locations within the thermal stack assembly 120 to monitor the temperature at the locations. Example locations include the DUT 42, the interface between TEC unit 130 and DUT 42, and the interface between TEC unit 130 and heat exchanger 126. Temperature monitoring system 80 thus controls thermal stack assembly 120 to heat and cool. DUT 42 as needed, e.g., according to a temperature profile.

Under the control of control computer 30, DUT power supply 40 provides electrical power to DUT 42 in one of a number of select operating modes. Example operating modes include: DC, AC, single pulse, and Pulse Width Modulation (PWM). In an example embodiment, DUT power supply 40 can be configured to simultaneously power one or more independent channels of DUT 42. In an example embodiment, DUT power supply 40 is configured so that certain electrical properties of DUT 42 can be measured and provided to control computer 30, such as current, voltage, pulse frequency, pulse duty cycle, pulse current low and pulse current high.

One of the main functions of temperature control system 50 is to put DUT 42 at a set-point temperature and then maintain the DUT at that temperature until a new set-point temperature is required. This involves setting and maintaining thermal stack assembly 120 at a select temperature, since the temperature of DUT 42 is assumed to be substantially equal to the temperature of the thermal stack assembly. This involves heating or cooling thermal stack assembly 120, since heat typically needs to be added or removed from DUT 42 as the DUT is operating at a select temperature set point in the temperature profile. Also, the temperature profile may require the temperature of DUT 42 to be raised and lowered over a given time interval, which also requires heating and cooling of thermal stack assembly 120.

### Electronic Control and Feedback

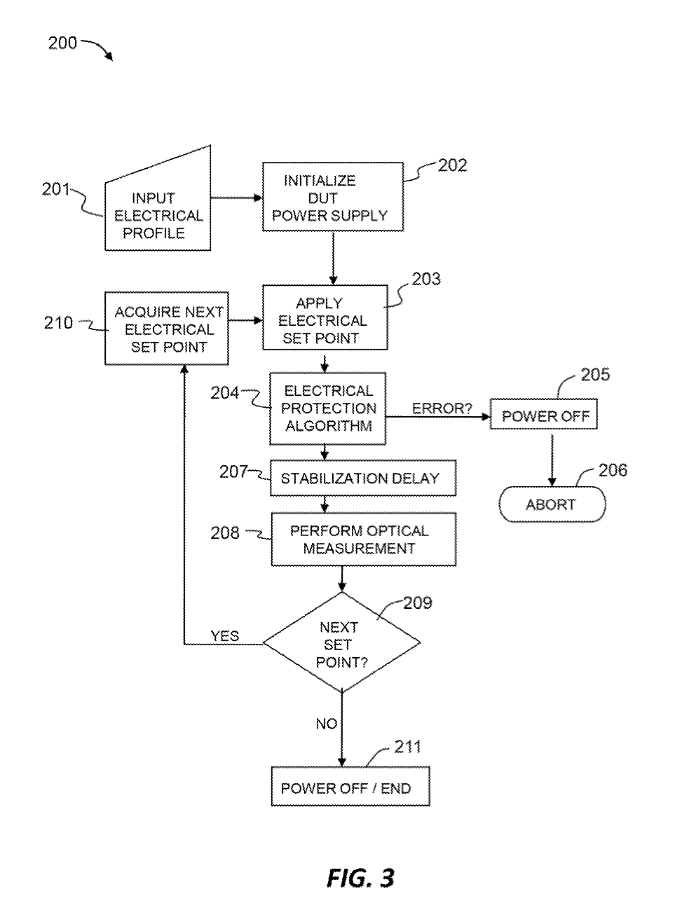

FIG. 3 is a flow diagram 200 that sets forth an example embodiment of an electrical control and feedback process for system 10. In 201, the electrical control and feedback process is initiated by a system user creating an electrical profile and inputting it to (which includes creating it in) control computer 30. The electrical profile is a parameterized list of electrical set points for DUT 42.

In 202, DUT power supply 40 is initialized to the first electrical set point defined in the electrical profile, and in 203 the electrical set point is applied to DUT 42. In 204, an electrical protection algorithm, which can be executed in one or both of DUT power supply 40 and the control software in control computer 30, verifies that there are no electrical problems, such as an open circuit, a closed circuit, or if the compliance voltage or compliance current for DUT 42 exceeded. In an example embodiment, the electrical protection algorithm is based on one or more safety parameters, such as current or voltage thresholds, that if exceeded indicate an electrical problem. If an electrical problem is detected, then the process proceeds to 205 where control computer 30 powers off DUT power supply 40 and the measurement process is aborted in 206.

If no electrical problems are detected in 204 by the electrical protection algorithm, then in 207 a stabilization delay as defined in the electrical profile is performed. This purpose of the stabilization delay is to allow DUT 42 to electrically and thermally stabilize prior to taking a measurement. After the stabilization delay of 207, then in 208 one or more optical measurements of DUT 42 at the given electrical set point of 203 are performed. In an example, the electrical, thermal (temperature) and optical parameters, (e.g., electrical current or power, DUT temperature, DUT spectrum, etc.) are sampled as near to the same time as possible.

After the one or more optical measurements of 208, then in 209 if additional electrical set points are specified in the electrical profile of 201, then in 210 another (e.g., the next) electrical set point is acquired from the electrical profile and the process is repeated from 203 to 209. Once the final optical measurement has been taken, then in 211 DUT power supply 40 is powered off and the process ends.

The various optical measurements are embodied in light processor signals S180 and stored in memory 34 as raw optical data, or processed directed by processor 32 and then stored in memory 34 as processed optical data. Since the electrical profile is also stored in memory 34, the optical measurements can be analyzed as a function of the electrical profile set points, thereby providing a picture of the optical performance of DUT 42 as a function of its electrical properties.

### Temperature Control and Feedback

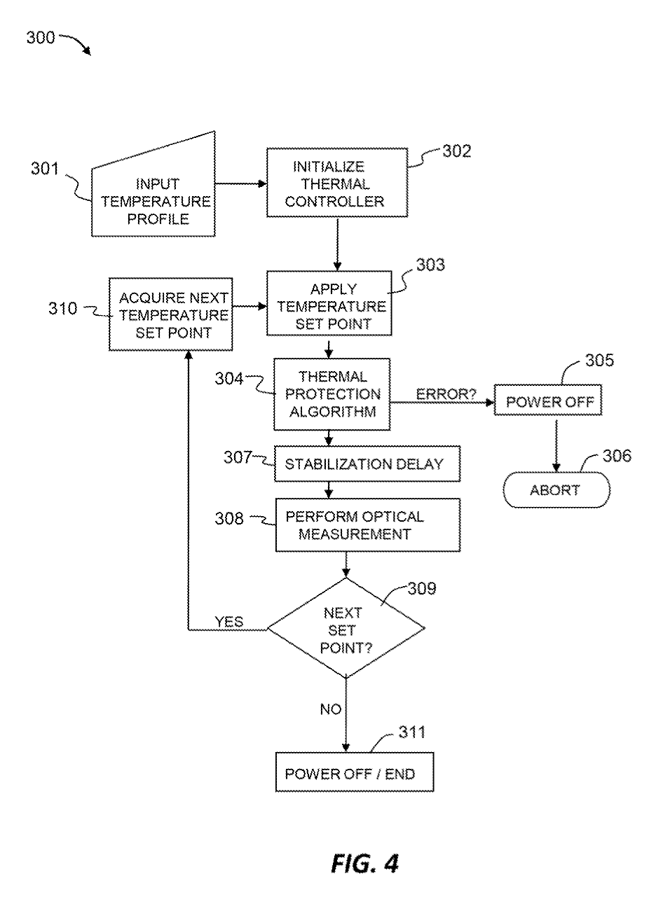

FIG. 4 is a flow diagram 300 similar to flow diagram 200 of FIG. 3 and that sets forth an example embodiment of a temperature control and feedback process for system 10. In 301, the temperature control and feedback process is initiated by the system user creating a temperature profile and inputting it or otherwise creating it in control computer 30. The user-defined profile is a list of temperature set points for DUT 42.

In 302, TEC controller 64 is initialized by computer controller 30 to the first temperature set point from the temperature profile, and in 303 the temperature set point is applied to DUT 42 via thermal stack 120. In 304, a temperature protection algorithm, which can be executed in one or both of the TEC controller 64 and in the control software of control computer 30, verifies that no temperature problems have been encountered, such as safety related thermal problems or an invalid temperature reading. In an example embodiment, the temperature protection algorithm is based on one or more safety parameters, such as temperature thresholds, that if exceeded indicate a thermal-based problem. If a thermal problem is detected (e.g., temperature measurements as reported by temperature monitor 100 to control computer 30 exceeds one or more temperature thresholds), then in 305, computer controller 30 instructs TEC controller 64 to power down H-bridge 66, and the process is aborted in 306.

If no thermal problems are detected in 304, then in 307 a stabilization delay as defined in the temperature profile of 301 is performed. This purpose of the stabilization delay is to allow DUT 42 to thermally stabilize prior to taking an optical measurement. In particular, the stabilization delay of 307 allows DUT 42 to reach the set-point temperature. After the stabilization delay, in 308 one or more optical measurements are performed. As with the electrical control and feedback process, in an example the electrical, thermal and optical parameters are sampled as near to the same time as possible.

After the one or more optical measurements of 308, then in 309 if additional temperature set points are specified in the electrical profile of 301, then in 310 another (e.g., the next) temperature set point is acquired and the process is repeated from 303 to 309. Once the final optical measurement has been taken, then in 311, TEC controller 64 powers off H-Bridge 66, and the process is ended.

Once again, the various optical measurements are embodied in light processor signals S180 and stored in memory 34 as raw optical data, or processed directed by processor 32 and then stored in memory 34 as processed optical data. Since the temperature profile is also stored in memory 34, the optical measurements can be analyzed as a function of the temperature profile set points, thereby providing a picture of the optical performance of DUT 42 as a function of its operating temperature. Further, this information can be combined with the optical measurements of the electrical control and feedback process 200 to provide a picture of the optical performance of DUT 42 as a function of its electrical properties and its operating temperature.

### Light Processor Control Process

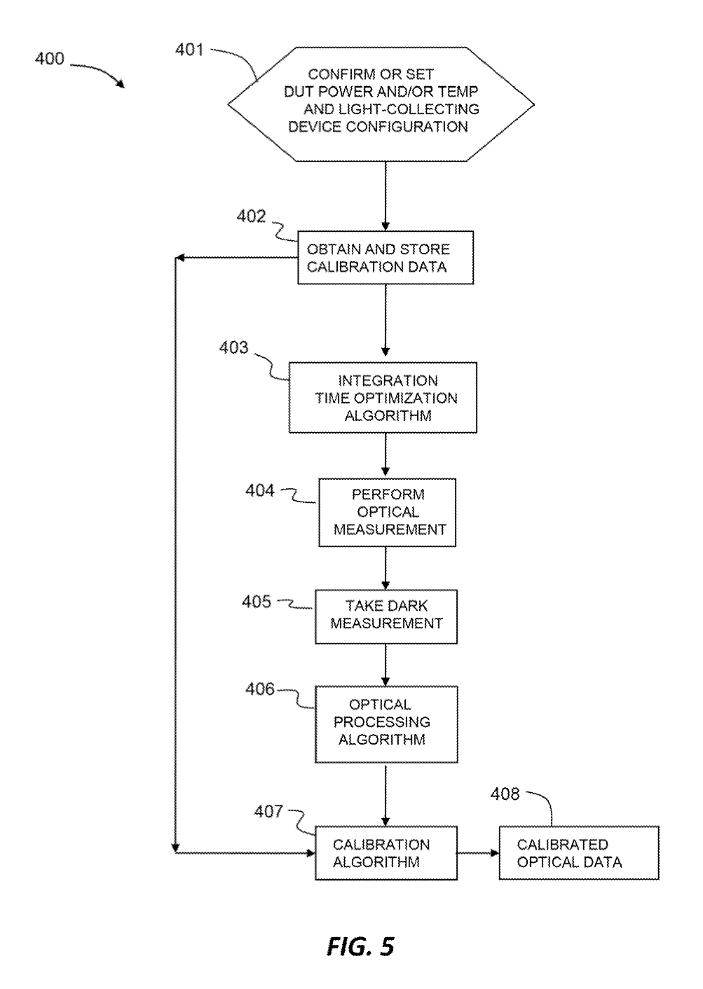

FIG. 5 is a flow diagram 400 that sets forth an example light processor control process for system 10. The'light processor control process is carried out in conjunction with the optical measurements taken in steps 208 and 308 of the electrical and temperature control processes described above.

In 401, system 10 is checked to make sure that light-collecting device 170 is properly configured relative to DUT 42 and light processor 180, and that the DUT is at the desired power level and/or temperature. In 402, optical calibration data is obtained and stored in control computer 30 (e.g., in memory 34). Note that in the case where there is no light-collecting device (e.g., the embodiment of system 10 of FIG. 1C), then 401 is simplified somewhat.

In 403, an integration time optimization algorithm is invoked to determine the integration time needed for light processor photosensor 182 to ensure the best signal to noise ratio possible in light processor signal S180 to ensure data accuracy.

Once the optimal integration time has been determined, then in 404 an optical measurement of DUT 42 is performed using the integration time established in 403. This generates light processor signals 5108 that are passed to control computer 30 to be processed by processor 32 running an optical processing algorithm. More specifically, during the optical measurement process of 403, light processor 180 receives light 43 from DUT 42 via light-collecting device 170 (FIGS. 1A, 1B) or directly (FIG. 1C). Light processor 180 is configured to process components of light 43. For example, in the case where light processor includes a spectrometer, light 43 is spectrally decomposed via the action of one or more diffraction gratings (not shown) into its wavelength components, which are then detected in corresponding regions (e.g., pixels) of photosensor 182. In this example, photosensor 182 may be a charge-coupled device (CCD) sensor. In an example where light processor 180 includes a colorimeter, light 43 is analyzed based on its color components, and this information is detected by photosensor 182 and embodied in electrical signal S180.

Generally speaking, photosensor 182 generates an electrical signal S180 representative of the optical content of light 43 as analyzed (processed) by light processor 180.

In 405, a “dark” measurement using the same integration time as used in 403 is taken to determine the dark noise level of photosensor 182, and a dark light processor signal S180D is passed to control computer 30 and to an optical processing algorithm therein. In an example embodiment, light processor 180 has a shutter (not shown) used to block light 43 and any other ambient light from hitting photosensor 182 to measure dark light processor signals S180D. In another example embodiment, dark measurements are taken prior to activating DUT 42. The dark measurement represented by dark light processor signal S180D is used to remove the dark noise level from the optical measurement in light processor signal S180.

In 406, an optical processing algorithm is run as described in greater detail below, and generates uncalibrated optical data. In 407, the outputted uncalibrated optical data is passed to a calibration algorithm, which accesses the optical calibration data of 402 and applies it to the uncalibrated optical data to compensate for various optical errors, as explained in greater detail below. The output of step 407 is calibrated optical data, shown as 408, which can be stored in memory 34 and also displayed on display unit 36.

### General Measurement Control Process

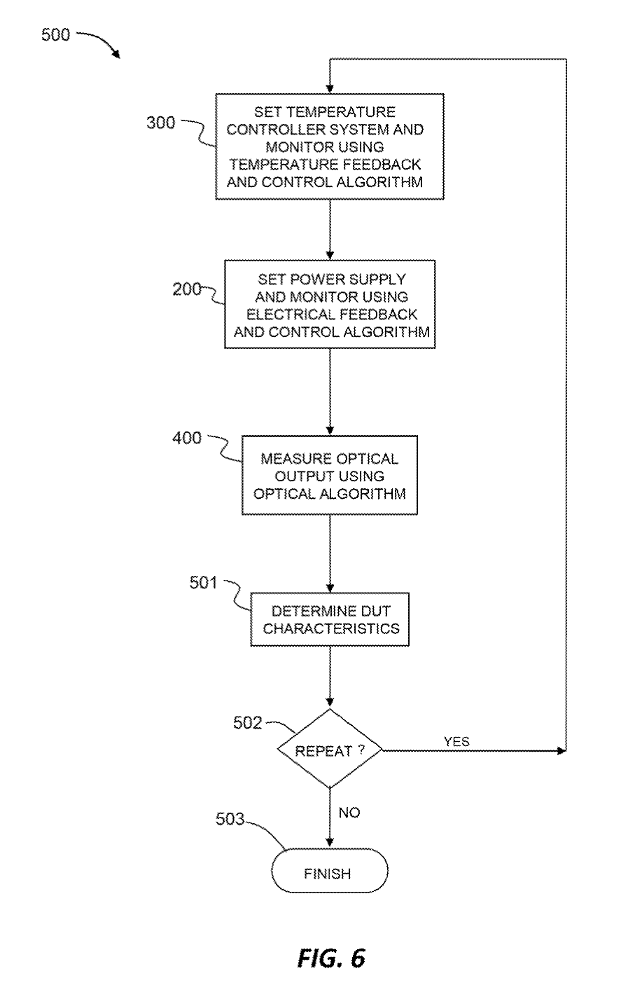

FIG. 6 is a flow diagram 500 that sets forth an example of the general measurement process that utilizes electrical control and feedback process 200 of FIG. 3, the temperature control and feedback process 300 of FIG. 4, and the light processor control process 400 of FIG. 5.

The general measurement control process 500 begins in one example by placing DUT 42 in a desired temperature condition by using the temperature control and feedback process 300. Process 500 then has control computer 30 place DUT 42 in a desired electrical condition using the electrical control and feedback process 200. Process 500 then takes an optical measurement using light processor control process 400. In 501, one or more DUT characteristics are determined (e.g., calculated) using the results of the optical measurements of 400 using a DUT characteristic calculation algorithm.

Example characteristics of DUT 42 that can be determined for each measurement taken by system 10 include electrical, temperature (thermal) and optical characteristics. Example electrical characteristics include current, voltage, pulse frequency, pulse duty cycle, pulse current low, pulse current high (which in an example are read from DUT power supply 40), power consumption (which is the current multiplied by voltage), and junction temperature (as described below). Example temperature (thermal) characteristics include various temperatures, such as the temperature of the front and back of TEC 130, the temperature of heat exchanger 126, temperature at base of DUT 42, temperature at any other external location on DUT 42 and the temperature of the cooling fluid at the cold and hot probes 92 and 94. The cooling fluid flow rate can also be calculated.

In an example embodiment, the temperature characteristics include measurements taken at various locations in thermal stack assembly 120, and the temperature measurements are assumed to correspond to the base temperature of DUT 42. In an example embodiment, the DUT base temperature is assumed to be substantially the same as the thermal stack assembly temperature as deduced from the one or more thermal stack assembly temperature measurements (e.g., the average of two or more of the temperature measurements).

Example optical characteristics include optical power (e.g., radiant and luminous flux), the sum of optical power at each wavelength, and various Chromaticities, such as CIE1931 Chromaticity per CIE1931, CIE1960 Chromaticity per CIE1960, CIE1964 Chromaticity per CIE1964, CIE1976 Chromaticity per CIE1976. Further example optical characteristics include Delta UV, Correlated Color Temperature (CCT), Color Purity, Dominant Wavelength, Complementary Wavelength, Peak Wavelength (i.e., wavelength of max power), the optical power full-width half-maximum (FWHM), Color Rendering Index (CRI) and Color Quality Scale (CQS).

A number of other DUT characteristics can be derived from combinations of electrical, thermal, and optical data, such as conversion efficiency from the radiant flux divided by electrical power; the luminous efficacy from the luminous flux divided by electrical power; the lighting efficiency from the luminous efficacy divided by 683.0, and the junction temperature.

Various CIE Chromaticities and other example characteristics are described in the following publications, all of which are incorporated by reference herein: CIE1931: Commission Internationale de l'Eclairage proceedings, 1931. Cambridge University Press, Cambridge, 1932; CIE1960: Commission internationale de l'Eclairage proceedings, 1959 (Brussels). Bureau de la CIE, Paris, 1960; CIE1964: Commission internationale de l'Eclairage proceedings, 1963 (Vienna). Bureau de la CIE, Paris, 1964; CIE1976: Recommendations on Uniform Color Spaces, Color-Difference Equations, Psychometric Color Terms. Bureau de la CIE, Paris, 1978. Delta UV: Schanda, Janos (2007). “3: CIE Colorimetry”. Colorimetry: Understanding the CIE System. Wiley Interscience. p. 37-46; CCT: McCamy, Calvin S. (April 1992); “Correlated color temperature as an explicit function of chromaticity coordinates,” Color Research & Application 17 (2): 142-144; Color Purity: Light-Emitting Diodes, Second Edition, E. Fred Schubert. Cambridge University Press, 2006, Colorimetry: Color Purity: 300-301; E. Fred Schubert, “Dominant Wavelength: Light-Emitting Diodes,” Second Edition, Cambridge University Press, 2006, Colorimetry: Color Purity: 300-301; CQS: W. Davis and Y. Ohno, “Toward an improved color rendering metric,” Fifth International Conference on Solid State Lighting, Proc. SPIE 5941, 59411G (2005); and Junction Temperature: Electronic Industries Alliance/JEDEC Solid State Technology Association, Standard: EIA/JESD51-1.

Example output of the software in control computer 30 includes one or more of the above-described characteristics and measurement parameters, as well as graphs, charts, etc. that plot any of the measured parameters or characteristics with respect to any another, including with grouping capabilities (e.g., different temperatures, different electrical currents, etc.).

In 502, the measurement control process may either be repeated by returning to 300, or terminated at 503.

### Calibration Control Process

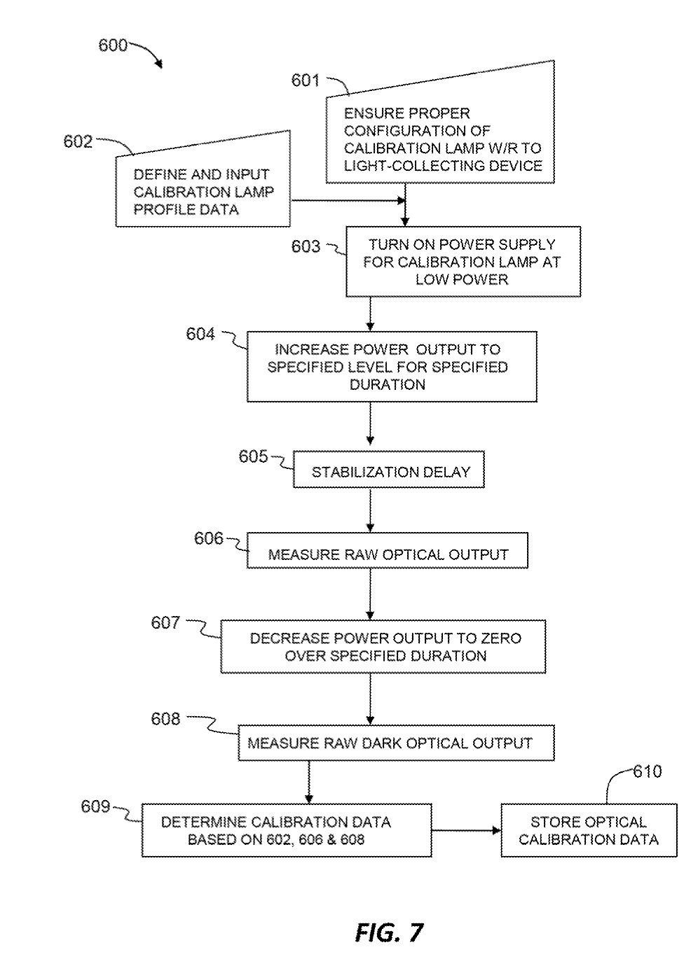

FIG. 7 is a flow diagram 600 that sets forth an example calibration control process. The purpose of the calibration control process is to calculate the correction factors, based on an optically known calibration lamp CL (FIG. 1) to be applied to the optical measurements to ensure that system 10 performs an accurate optical measurement of DUT 42. In an example embodiment, the calibration control process also compensates for any absorption errors introduced by DUT 42.

The calibration process 600 preferably takes into account the non-linearity of light processor photosensor 182, as well as geometric features within light-collecting device 170 (if such device is used), and absorption and reflection properties of DUT 42. The calibration control process 600 starts in 601 by checking or ensuring that the light-collecting device 170 is properly configured and that the calibration lamp CL and DUT 42 have been properly arranged relative to the light-collecting device if such device is used.

In 602, the user inputs or otherwise creates in control computer 30 a calibration lamp profile. The calibration lamp profile defines, for example, the power level and mode in which the calibration lamp CL is to be driven by DUT power supply 40, the rate at which DUT 42 is to be driven to the desired power level, the duration of time needed for the calibration lamp to stabilize once the desired power level has been reached, and the rate at which the DUT is to be driven back to zero power output, in order to reduce electrical and thermal stresses placed on calibration lamp CL. Note that it is not necessary to vary the temperature of calibration lamp CL, so that the calibration lamp essentially replaces the thermal stack assembly (see FIG. 1A).

In 603, DUT power supply 40 is turned on at a very low initial power level. Then, in 604 the electrical power provided by DUT power supply 40 is increased to the desired power level and at a rate specified by the calibration lamp profile of 602. Once the desired power level has been reached, then in 605 a specific time delay as defined by the calibration lamp profile of 602 is allowed to elapse while the calibration lamp stabilizes.

In 606, a raw light measurement is taken by light processor 180 and the resulting light processor signals S180 representative of the raw optical output of calibration lamp CL is passed to control computer 30. In 607, the electrical power is decreased to zero output at the rate specified by the calibration lamp profile of 602. In 608, a raw dark measurement is taken using light processor 180 and the resulting dark light processor signal S180D is passed to control computer 30.

In 609, calibration data is determined (e.g., calculated) based on the user-supplied calibration lamp data of 602 and the measurements of 606 and 608, as well as factors affecting these optical measurements. In 610, the calibration data of 609 is stored in control computer 30, e.g., in memory 34.

### Calibration Lamp Transfer Control Process

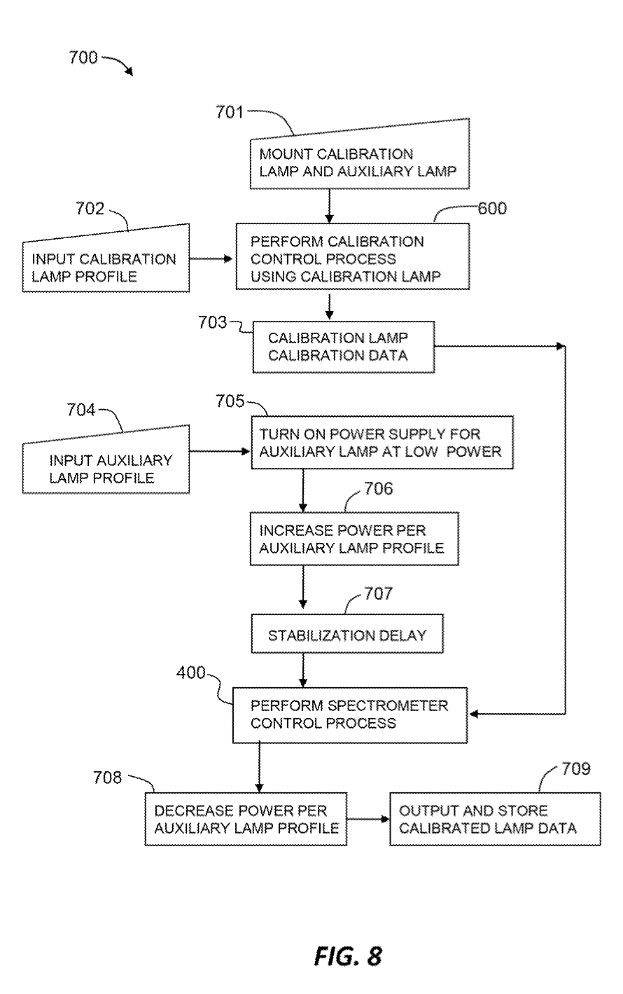

FIG. 8 is a flow diagram that sets forth an example calibration lamp transfer control process. The purpose of this process is to transfer the calibration data of one lamp to another to create a new calibration lamp CL. This process utilizes the light processor control processes 400 of FIG. 5 and the calibration control process 600 of FIG. 6.

In 701, calibration lamp CL is mounted on DUT fixture 122, and auxiliary lamp 186 is placed in position if it is not already there (see FIG. 1A). In 702, a calibration lamp profile is inputted to control computer 30. In 600, the calibration control process is initiated and the output 703 is the calibration data for the calibration lamp, which is used at a later time.

In 704, an auxiliary lamp profile is inputted into control computer 30. The auxiliary lamp profile corresponds to and provides the same function as the calibration lamp profile. In 705, DUT power supply 40 is turned on at a very low power level. In 706, the power from DUT power supply 42 is increased to the desired power level at a rate specified by the auxiliary lamp profile. Once the desired level has been reached, then in 707 a stabilization delay, as defined by the auxiliary lamp profile, is imposed while the auxiliary lamp stabilizes.

Next, the light processor control process 400 is performed using the calibration lamp calibration data from 703 as the process input. In 708, the power from DUT power supply 42 power is decreased to zero output at a rate specified by auxiliary lamp profile of 704. In 709, the calibrated lamp data from carrying out the light processor control process 400 on the auxiliary lamp is then outputted to a file or stored, e.g., in memory 34 of control computer 30.

### Example Optical Characterization Plots

As discussed above, control computer 30 receives and processes light processor signals 5180 under the operation of processor 32 and instructions (software) stored either in memory 34 or directly in the processor. The instructions constitute the optical processing algorithm of step 406 in light processor control process 400. The optical processing algorithm calculates, based on light processor signals 5180 (and in some cases dark signal S180D) and the electrical profile and/or the temperature profile, one or more optical characterizations of DUT 42 as a function of the DUT's electrical and/or temperature properties, i.e., the electrical power inputted to DUT and/or the operating temperature of the DUT. These properties are varied in a controlled manner by DUT power supply 42 and temperature control system 50 under the operation of control computer 30.

FIG. 9 is a plot of the radiant flux (Watts) versus wavelength (nm) for an amber LED as an example light-emitting DUT 42. System 10 varied the temperature from 15° C. to 95° C. and varied the current from 25 mA to 450 mA in accordance with the general measurement control process of FIG. 6 to obtain the different curves (spectra) shown in the plot.

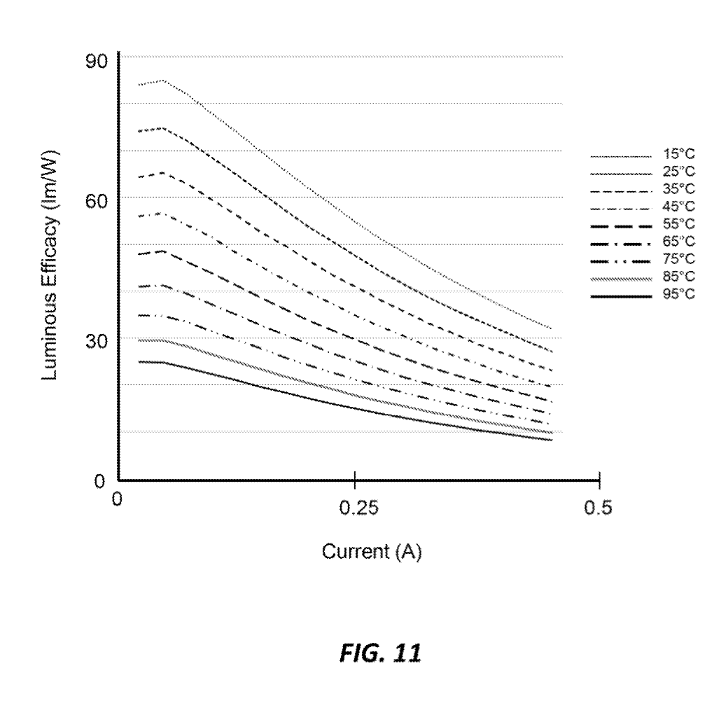

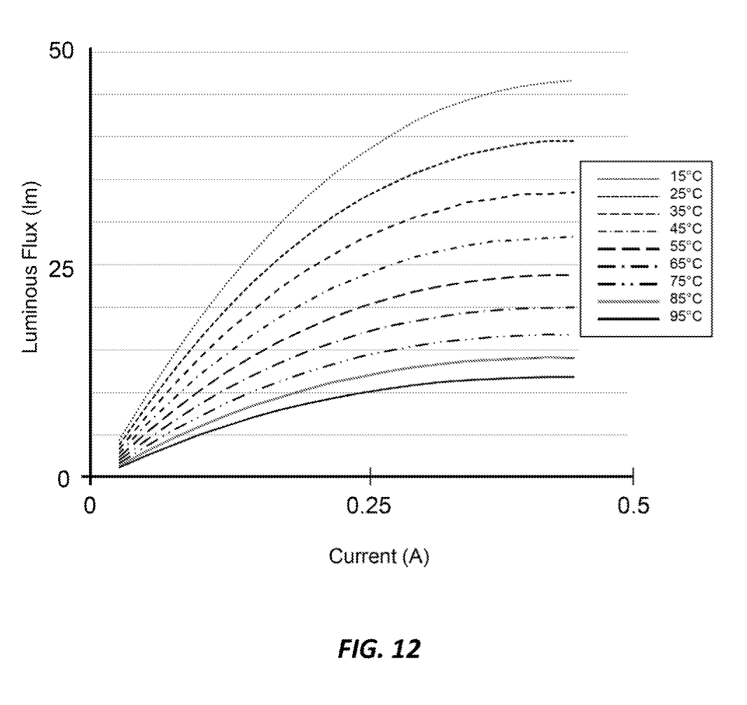

FIG. 10 is plots both temperature (° C.) and current (A) versus step number and shows the temperature profile and electrical profile implemented by control computer 30 in obtaining the curves shown in FIG. 9, as well as the curves in FIGS. 11 and 12, discussed below. The temperature profile has increments (steps) of 10° C. while the electrical profile has current increments (steps) of 25 mA.

FIG. 11 is a plot of the luminous efficacy (lm/W) vs. electrical current (A) for an amber LED as the light-emitting DUT 42, wherein the curves were obtained using the temperature profile and electrical profile of FIG. 10.

FIG. 12 is a plot of the luminous flux (lm) vs. electrical current (A) for an amber LED as the light-emitting DUT 42, wherein the curves were obtained using the temperature profile and electrical profile of FIG. 10.

The systems and methods of the present disclosure have utility with respect to many applications within the field of lighting test and measurement. Such applications include the measurement of light-emitting diodes (LEDs), organic light-emitting diodes (OLEDs), Light Emitting Polymer (LEP), Organic Electro Luminescence (OEL), laser diodes, lasers and virtually any type of solid-state or organic semiconductor light source, in any sort of configuration. The automation of system 10 addresses the complexities of orchestrating complex optical characterization tests, while the system's modularity provides flexibility in the manipulation and repeatability of test parameters, as well as the calibration of the system.

While the present disclosure has been described in connection with preferred embodiments, it will be understood that it is not so limited. On the contrary, it is intended to cover all alternatives, modifications and equivalents as may be included within the spirit and scope of the disclosure as defined in the appended claims.

What is claimed is:

1. A system for characterizing a light-emitting device having an optical output that varies with inputted electrical power and temperature, comprising:
a thermal stack assembly in thermal communication with and that operably supports the light-emitting device;
a light processor optically coupled to the light-emitting device and adapted to convert optical outputs of the light-emitting device into corresponding electrical signals;
a temperature control system operatively connected to the thermal stack assembly and configured to vary a temperature of the thermal stack in a controlled manner to vary the temperature of the light-emitting device;
a power supply electrically coupled to the light-emitting device and configured to provide electrical power thereto in a varied and controlled manner; and
a control computer electrically connected to the power supply, the light processor and the temperature control system, and configured to cause the power supply and temperature control system to vary the electrical power inputted to and the temperature of the light-emitting device, and store and process the corresponding light processor electrical signals.

2. The system of claim 1, further including a light-collecting device through which the light-emitting device and the light processor are optically coupled.

3. The system of claim 2, wherein the light-collecting device includes at least one of an optical system and a light-integrating sphere.

4. The system of claim 1, wherein the light processor includes a spectrometer or a colorimeter.

5. The system of claim 1, wherein the temperature control system includes temperature control electronics and a cooling fluid system, and wherein the thermal stack assembly includes a thermoelectric cooler electrically connected to the temperature control electronics and a heat exchanger fluidly connected to the cooling fluid system and in thermal communication with the thermoelectric cooler.

6. The system of claim 5, wherein the cooling fluid system includes a cooling fluid in the form a gas or a liquid.

7. The system of claim 5, wherein the temperature control electronics includes a thermoelectric cooler controller electrically connected to an H-bridge, and a thermoelectric cooler power supply electrically connected to the H-bridge, wherein the temperature control electronics is electrically connected to the thermoelectric controller through the H-bridge.

8. The system of claim 5, wherein the temperature control system includes a temperature monitor.

9. The system of claim 1, wherein the control computer includes a processor and computer-readable instructions that cause the processor to cause the power supply and temperature control system to vary in a controlled manner at least one of the electrical power inputted to and the temperature of the light-emitting device.

10. The system of claim 1, wherein the power supply is configured to provide the electrical power to the light-emitting device, under the operation of the control computer, in at least one of the following forms:
a) a DC current or voltage signal in a single channel configuration;
b) an AC voltage or current signal in a single channel configuration;
c) a pulse-width modulation (PWM) current or voltage signal in a single channel configuration;
d) a single pulse current or voltage signal in a single channel configuration; and
e) a current or voltage signal over multiple channels.

11. The system of claim 10, wherein the power supply is configured to measure at least one electrical property of the light-emitting device selected from the group of electrical properties comprising: current, voltage, pulse frequency, pulse duty cycle, pulse current low and pulse current high.

12. The system of claim 1, wherein the light processor is triggered with a trigger signal that is synchronous with a power supply signal.

13. The system of claim 12, wherein the power supply signal is a pulse-width modulation signal having a period, and wherein the light processor has an integration time that is an integer multiple of the PWM period.

14. A method of automatically characterizing a light-emitting device having an optical output that depend on electrical and temperature properties of the light-emitting device, comprising:
establishing in a control computer an electrical profile and a temperature profile for the light-emitting device;
automatically controlling with the control computer varying amounts of electrical power to the light-emitting device according to the electrical profile;
automatically controlling, via the control computer, the temperature of the light-emitting device according to the temperature profile;
converting optical outputs emitting by the light-emitting device in response to the electrical and temperature profiles into corresponding electrical signals; and
processing the electrical signals to establish at least one optical characterization of the light-emitting device as a function of at least one of the applied electrical power and the light-emitting device temperature.

15. The method of claim 14, wherein converting the optical outputs to electrical signals includes:
inputting light from the light-emitting device into a light-collecting device; and
providing light from the light-collecting device to a light processor configured to form light spectra and detect the light spectra with a photodetector that converts the light spectra into the electrical signals.

16. The method of claim 14, including controlling the light-emitting device temperature using a thermoelectric cooler.

17. The method of claim 14, including applying the electrical power to the light-emitting device using a power supply and in at least one or more of the following forms:
a) a DC current or voltage signal in a single channel configuration;
b) an AC voltage or current signal in a single channel configuration;
c) a pulse-width modulation (PWM) current or voltage signal in a single channel configuration;
d) a single pulse current or voltage signal in a single channel configuration; and
e) a current or voltage signal over multiple channels.

18. The method of claim 14, wherein the electrical and temperature profiles are embodied in a computer-readable medium that includes instructions that cause the control computer to control a) the amounts of electrical power applied to the light-emitting device, and b) the temperature of the light-emitting device.

19. The method of claim 14, wherein processing the electrical signals includes determining from the optical outputs at least one optical characterization from the group of optical characterizations comprising: optical power, radiant flux, luminous flux, luminous efficacy, chromaticity, color purity, dominant wavelength, complimentary wavelength, peak wavelength, optical full-width half-maximum, color rendering index, color quality scale, delta UV and correlated color temperature.

20. The method of claim 14, further comprising performing safety monitoring based on at least one of the electrical power inputted to and the temperature of the light-emitting device.

21. The method of claim 14, further comprising performing a calibration process.

22. The method of claim 14, further comprising performing an automated process for transferring a calibration standard from a first calibration lamp to a second calibration lamp.

23. The method of claim 14, wherein processing the electrical signals includes correcting for light-emitting device absorption.

24. The method of claim 14, including automatically calibrating the light-emitting device based on light output from a calibration lamp.

25. The method of claim 14, further comprising performing a calibration between first and second lamps optically coupled to a light integrating device.

26. The method of claim 14, wherein the light-emitting device includes a junction, and further comprising calculating a junction temperature.

27. A method of automatically characterizing a light-emitting device having an optical output that depends on its electrical and temperature properties, comprising:
a) under the control of a control computer, automatically performing at least one of i) applying to the light-emitting device varying amounts of electrical power based on an electrical profile, and ii) controlling the temperature of the light-emitting device based on a temperature profile;
b) receiving, in a light processor, light emitted from the light-emitting device during act a), and converting the received light into electrical signals representative of the corresponding optical outputs; and
c) processing the electrical signals to establish an optical characterization of the light-emitting device as a function of at least one of the applied electrical power and the temperature of the light-emitting device.

28. The method of claim 27, further comprising collecting the light from the light emitting device with a light-collecting device prior to receiving the light in the light processor.

29. The method of claim 28, wherein the light-collecting device includes at least one of an optical system and a light-integrating sphere.

30. The method of claim 27, further comprising varying the temperature of the light-emitting device by heating and cooling the light-emitting device using a thermal stack assembly that is in thermal communication with the light-emitting device and that includes a heat exchanger and a thermoelectric cooler.

31. The method of claim 27, wherein automatically applying the electrical power includes controlling a power supply connected to the light-emitting device with a control computer having instructions stored therein on a computer-readable medium that cause the controller to control the power supply based on the electrical profile.

32. The method of claim 27, wherein the electrical and temperature profiles are stored in a computer-readable medium in the computer controller.

33. The method of claim 27, wherein processing the electrical signals includes determining from the optical outputs at least one optical characterization from the group of optical characterizations comprising: optical power, radiant flux, luminous flux, luminous efficacy, chromaticity, color purity, dominant wavelength, complimentary wavelength, peak wavelength, optical full-width half-maximum, color rendering index, color quality scale, delta UV and correlated color temperature.
